(19) United States
(12) Patent Application Publication
(10) Pub. No.: US 2007/0235771 A1
(43) Pub. Date: Oct. 11, 2007

(54) Semiconductor image sensor and method for fabricating the same

(76) Inventor: Yan-Hsiu Liu, Tainan City (TW)

Correspondence Address: J.C. Patents, Inc., 4 Venture, Suite 250, Irvine, CA, 92618, US

(21) Appl. No.: 11/399,126

(22) Filed: Apr. 5, 2006

(51) Int. Cl. H01L 21/00

(52) U.S. Cl. 257/223; 438/57; 438/241

(57) ABSTRACT

A semiconductor image sensor and a method for fabricating the same are described. The semiconductor image sensor includes a substrate having at least a photoactive region therein and an IR cutting layer over the photoactive region.

### BACKGROUND OF THE INVENTION

1. Field of the Invention

The present invention relates to a semiconductor apparatus. More particularly, the present invention relates to a semiconductor image sensor and a method for fabricating the same.

2. Description of the Related Art

The semiconductor image sensor is applied more and more widely because of simpler fabricating process and lower cost. However, a silicon-based semiconductor image sensor also senses infrared (IR) light making the image-recording incorrect, so that an IR filter needs to be mounted on the lens of an image recording apparatus with a core of a semiconductor image sensor before use. This causes some inconvenience in the design and use of the image recording apparatus and raises the cost of the same.

### SUMMARY OF THE INVENTION

Accordingly, this invention provides a semiconductor image sensor that can be utilized without an IR filter mounted on the lens of the image recording apparatus.

This invention also provides a method for fabricating a semiconductor image sensor of this invention.

The semiconductor image sensor of this invention includes a substrate having at least a photoactive region therein and an IR cutting layer disposed over the photoactive region.

In some embodiments, the above IR cutting layer may be an IR absorption/reflection layer as a layer effective in IR absorption, IR reflection or both.

The IR cutting layer may include a base material and an IR cutting material added in the base material. Alternatively, the base material of the IR cutting layer is directly an IR cutting material.

In some embodiments, the IR cutting layer may be disposed merely for cutting IR light. In other embodiments, the IR cutting layer may have at least one function other than IR cutting.

For example, the IR cutting layer may also serve as a color filter. Such an IR cutting layer may include a photoresist material containing an IR absorption/reflection dye as a dye effective in IR absorption, IR reflection or both. The IR absorption dye may be selected from the group consisting of at least cyanine dyes, squarilium dyes, naphthoquinone dyes, quinone imine dyes, quinone diimine dyes, phthalocyanine, tetradehydrocholine and ethylene-1,2-dithiol metal complexes.

In other examples, the IR cutting layer may also serve as a dielectric layer. The dielectric layer may include at least one of multiple inter-layer/inter-metal dielectric films, and the material of the dielectric layer may be selected from the group consisting of at least Ta₂O₅, TiO₂, silicon monoxide (SiO), ZrO₂, MoO₂, ZnO₂, InO₂, CrO₂, Al₂O₃, HfO₂ and zinc sulfide (ZnS). Alternatively, the IR cutting layer may also serve as a passivation layer or a planarizing layer.

In some embodiments, the IR cutting layer may include multiple functional layers having different functions other than IR cutting. The functional layers may include at least two of a dielectric layer, a passivation layer, a color filter and a planarizing layer that are stacked from bottom to top. When the functional layers together serving as the IR cutting layer include the dielectric layer and the passivation layer, the dielectric layer may include multiple inter-layer/inter-metal dielectric films. The materials of the inter-layer/inter-metal dielectric films and the passivation may be selected from the group consisting of at least Ta₂O₅, TiO₂, SiO, ZrO₂, MoO₂, ZnO₂, InO₂, CrO₂, Al₂O₃, HfO₂ and ZnS.

Moreover, the above semiconductor image sensor may further include a microlens disposed over the IR cutting layer over the photoactive region for focusing visible light.

A type of semiconductor image sensor of this invention include a substrate, a dielectric layer, a passivation layer, a color filter array, a planarizing layer and an IR cutting layer. The substrate having therein at least multiple photoactive regions arranged in an array. The dielectric layer is on the substrate, having a circuit therein. The passivation layer is disposed on the dielectric layer and the color filter array on the passivation layer, wherein each color filter is disposed over one photoactive region. The planarizing layer covers the color filter array. The IR cutting layer is disposed over the photoactive region.

The above IR cutting layer may includes at least one of the dielectric layer, the passivation layer, the color filter array and the planarizing layer. Alternatively, the IR cutting layer may be a layer disposed between the dielectric layer and the passivation layer, between the passivation layer and the color filter array or between the color filter array and the planarizing layer, or a layer disposed on the planarizing layer.

In terms of optical property, the IR cutting layer may include an IR absorption/reflection layer. When the IR cutting layer includes the color filter array, the material of the color filter array may be a photoresist material that contains an IR absorption/reflection dye. Examples of the IR absorption dye are the same as above.

In an embodiment, the dielectric layer in the above type of semiconductor image sensor of this invention may include multiple inter-layer/inter-metal dielectric films, while the IR cutting layer may include at least one of the inter-layer/inter-metal dielectric films. The material of the at least one inter-layer/inter-metal dielectric film may be selected from the group consisting of at least Ta₂O₅, TiO₂, SiO, ZrO₂, MoO₂, ZnO₂, InO₂, CrO₂, Al₂O₃, HfO₂ and ZnS. The IR cutting layer may further include the passivation layer, while the materials of the passivation layer and the at least one inter-layer/inter-metal dielectric films forming the IR cutting layer may be selected from the group consisting of at least Ta₂O₅, TiO₂, SiO, ZrO₂, MoO₂, ZnO₂, InO₂, CrO₂, Al₂O₃, HfO₂ and ZnS.

Moreover, the above type of semiconductor image sensor may further include a microlens array on the planarizing layer and an encapsulant layer covering the microlens array and the planarizing layer, wherein each microlens is disposed over one color filter. The encapsulant layer is preferably conformal to the surface formed by the microlens array and the planarizing layer.

The method for fabricating a semiconductor image sensor of this invention is described below. A substrate formed with at least a photoactive region therein is provided, and then an IR cutting layer is formed over the photoactive region. The IR cutting layer may be an IR absorption/reflection layer, for example.

The IR cutting layer may be formed by forming a layer of a base material over the substrate and adding an IR cutting material during the formation of the layer of the base material. Alternatively, the base material of the IR cutting layer is directly an IR cutting material.

In some embodiments, the IR cutting layer is formed merely for IR cutting. In other embodiments, the IR cutting layer has at least one function other than IR cutting. 10021 For example, the IR cutting layer may also serve as a color filter, wherein the IR cutting layer may include a photoresist material containing an IR absorption/reflection dye. The IR cutting layer may alternatively include at least two functional layers each having a least one function other than IR-cutting, wherein the functional layers may be formed contiguous or non-contiguous. For example, the IR cutting layer may include a dielectric layer and a passivation layer thereon that are formed contiguous, wherein the dielectric layer may include multiple inter-layer/inter-metal dielectric films. The materials of the inter-layer/inter-metal dielectric films and the passivation layer may be selected from the group consisting of at least Ta₂O₅, TiO₂, SiO, ZrO₂, MoO₂, ZnO₂, InO₂, CrO₂, Al₂O₃, HfO₂ and ZnS.

In addition, any of the above-mentioned semiconductor image sensors may be a CMOS image sensor (CIS) or a charge coupled device (CCD) image sensor.

Since an IR cutting layer is directly formed over the photoactive region of the semiconductor image sensor, the lens of an image recording apparatus with the semiconductor image sensor as a core does not need an IR filter. Hence, the design and use of the image recording apparatus with a core of a semiconductor image sensor is more convenient, and the cost for an IR filter can be saved.

It is to be understood that both the foregoing general description and the following detailed description are exemplary, and are intended to provide further explanation of the invention as claimed.

### BRIEF DESCRIPTION OF THE DRAWINGS

FIG. 1 illustrates a cross-sectional-view of a semiconductor image sensor according to a first embodiment of this invention.

FIG. 2 illustrates a cross-sectional-view of a semiconductor image sensor according to a second embodiment of this invention.

FIG. 3 illustrates a cross-sectional-view of a dielectric layer and a passivation layer thereon in the structure of a semiconductor image sensor according to a third embodiment of this invention.

### DESCRIPTION OF THE PREFERRED EMBODIMENTS

It is firstly noted that though each semiconductor image sensor structure in the embodiments of this invention includes a substrate with a photoactive region therein, a dielectric layer with a circuit therein, a passivation layer, a color filter array, a passivation layer, a microlens array and an encapsulant layer, the IR-cutting design of this invention is not restricted to apply to such semiconductor image sensor structures but can be applied to any other semiconductor image sensor structure including a photoactive region. The application method may be: forming a layer merely for cutting IR over the photoactive region, making the base material of at least one functional layer over the photoactive region contain an IR cutting material, forming at least one functional layer over the photoactive region directly based on IR cutting material, or making the base material of at least one functional layer contain an IR cutting material as well as forming at least one other functional layer directly based on IR cutting material. A functional layer is defined hereinafter as a layer having at least one function other than IR cutting.

Moreover, “an IR cutting layer” in this invention does not only mean a single layer capable of cutting IR light, but may alternatively mean a combination of multiple layers merely for cutting IR light, a combination of multiple functional layers also capable of cutting IR light, or a combination of at least one layer merely for cutting IR light and least one functional layer also capable of cutting IR light, wherein the multiple layers may be formed/arranged contiguous or non-contiguous.

On the other hand, in terms of the optical property, the IR cutting layer is usually an IR absorption/reflection layer, which may be formed by adding an IR absorption/reflection material in a base material or be formed directly from an IR absorption/reflection material as a base material. It is noted that the term “absorption/reflection” means absorption, reflection, or both absorption and reflection in this invention.

### First Embodiment

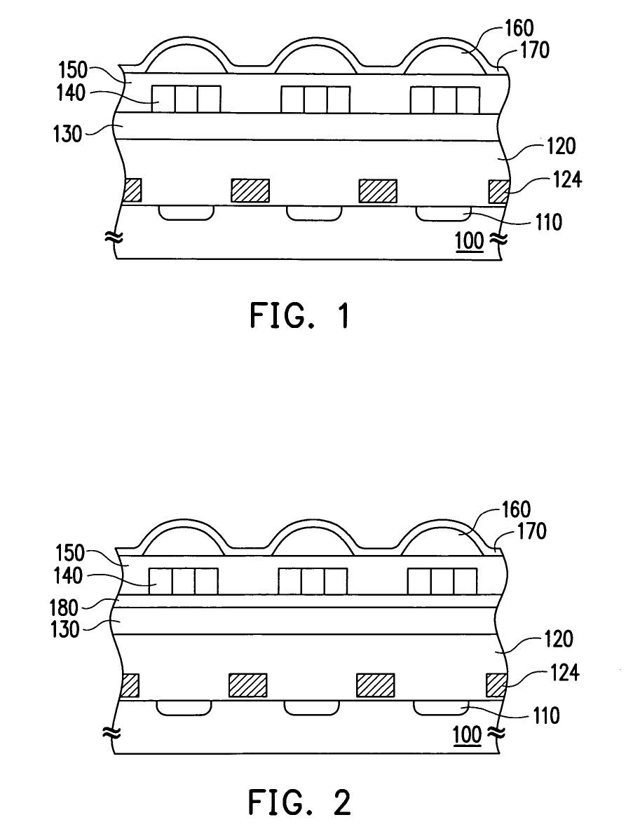

FIG. 1 illustrates a cross-sectional-view of a semiconductor image sensor according to the first embodiment of this invention. The semiconductor image sensor may be a CMOS image sensor (CIS) or a charge coupled device (CCD) image sensor, including a semiconductor substrate 100, a photoactive region 110, a dielectric layer 120, a passivation layer 130, a color filter array 140, a passivation layer 150, a microlens array 160 and an encapsulant layer 170, wherein at least one of the dielectric layer 120, the passivation layer 130, the color filter array 140 and the passivation layer 150 also has IR-cutting capability. When the dielectric layer 120 also has IR-cutting capability, it may be all portions, or one or more portions, of the dielectric layer 120 that have IR-cutting capability. Moreover, when there are multiple layers having IR-cutting capability in each of this and the following embodiments, the multiple layers are together called an IR cutting layer no matter what functions they have respectively.

The substrate 100 may be a silicon substrate, or a substrate made from any other semiconductor material having a band gap corresponding to the wavelengths of visible lights. The photoactive region 110 is a doped region formed in the substrate 100, having a conductivity type different from that of the substrate 100 so that a PN diode capable of absorbing visible light and causing photocurrent is formed.

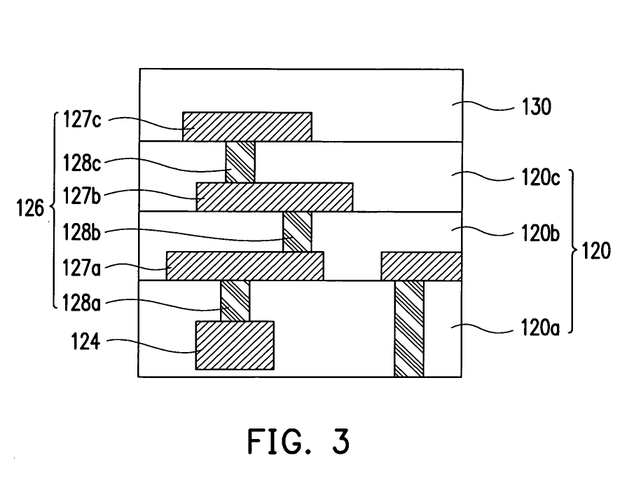

The dielectric layer 120 is disposed on the substrate 100, usually including multiple inter-layer/inter-metal dielectric films and formed therein with a circuit needed by the semiconductor image sensor. When the image sensor is a CMOS image sensor, the circuit includes the gates 124 of the CMOS transistors and an interconnect structure (e.g., 126 in FIG. 3) that is electrically connected with the gates 124. The multiple inter-layer/inter-metal dielectric films hereinafter mean a stacked structure of at least one inter-layer dielectric (ILD) film and at least one inter-metal dielectric (IMD) film. In the illustrated type of semiconductor image sensor structure, there are usually one ILD film and two to four IMD films. To make the dielectric layer 120 have IR cutting capability, it is possible to add a colorless IR cutting material in the base dielectric material of at least one of the inter-layer/inter-metal dielectric films or to form at least one of the inter-layer/inter-metal dielectric films directly from a colorless IR-cutting dielectric material like Ta₂O₅, TiO₂, SiO, ZrO₂, MoO₂, ZnO₂, InO₂, CrO₂, Al₂O₃, HfO₂, or ZnS, etc., as a base material. The above-listed IR-cutting dielectric materials can reflect as well as absorb IR light. When one or more inter-layer/inter-metal dielectric films are directly formed from at least one base material capable of reflecting and absorbing IR light, the thickness of the inter-layer/inter-metal dielectric film(s) can be adjusted to cause destructive interference between the incident, the reflective and the multi-reflective IR lights to further decrease the intensity of the IR light reaching the photoactive regions 110.

When there are more than one inter-layer/inter-metal dielectric films having IR cutting capability, the inter-layer/inter-metal dielectric films may be formed/arranged contiguous or non-contiguous. In addition, when there are more than one inter-layer/inter-metal dielectric films directly formed from IR-cutting dielectric, the materials of the inter-layer/inter-metal dielectric films may be the same or different.

The passivation layer 130 is disposed on the dielectric layer 120, usually including SiO₂ or SiN. To make the passivation layer 130 have IR cutting capability, it is possible to add a colorless IR cutting material in the base material of the passivation layer 130 or to form the passivation layer 130 from a colorless IR-cutting material like Ta₂O₅, TiO₂, SiO, ZrO₂, MoO₂, ZnO₂, InO₂, CrO₂, Al₂O₃, HfO₂ or ZnS, etc. as a base material. When the passivation layer 130 is formed from a base material capable of reflecting and absorbing IR light like one of the above-listed, the thickness of the passivation layer 130 can be adjusted to cause destructive interference of IR light to further decrease the IR intensity to the photoactive regions 110.

The color filter array 140 is disposed on the passivation layer 130, usually including red, blue and green color filters regularly arranged into an array. The base material of the color filter array 140 may be a photoresist material like a polyacrylic photoresist material so that the color filter array 140 can be formed through lithography. To make the passivation layer 130 have IR cutting capability, it is possible to add the red, blue and green photoresist materials of the three-color filters with respective IR absorption/reflection dyes and then conduct respective coating-definition processes of the three photoresist materials in sequence, wherein the coating may be spin-on coating. Examples of the IR absorption dyes include cyanine dyes, squarilium dyes, naphthoquinone dyes, quinone imine dyes, quinone diimine dyes, phthalocyanine, tetradehydrocholine and ethylene-1,2-dithiol metal complexes, etc.

The planarizing layer 150 covers the color filter array 140 and the passivation layer 130 to form a planar surface. The material of the planarizing layer 150 may be a polyacrylic resin that can be applied using a coating method like spin-on coating. To make the planarizing layer 150 capable of cutting IR light, it is possible to add a colorless IR cutting material like a powder of Ta₂O₅, TiO₂, SiO, ZrO₂, MoO₂, ZnO₂, InO₂, CrO₂, Al₂O₃, HfO₂ or ZnS, etc., in the base material of the planarizing layer 150.

The microlens array 160 is disposed on the planarizing layer 150, wherein each microlens has a convex shape. The microlens array 160 may be formed by forming a colorless photoresist layer on the planarizing layer 150, patterning the photoresist layer into an array of island patterns and then baking the island patterns to round them. The microlens array 160 serves to increase the light density on the photoactive region and thereby improve the sensitivity of the semiconductor image sensor.

The encapsulant layer 170 covers the planarizing layer 150 and the microlens array 160 for preventing invasion of moisture or other contaminants in the environment. The encapsulant layer 170 preferably includes a material with a refractive index smaller than that of the material of the microlens array 160 and is preferably conformal to the surface formed by the planarizing layer 150 and the microlens array 160 together, so as to improve the focusing effect of the microlens array 160.

### Second Embodiment

FIG. 2 illustrates a cross-sectional-view of a semiconductor image sensor according to a second embodiment of this invention.

The structure of this semiconductor image sensor is different from that of the semiconductor image sensor in the first embodiment in that none of the dielectric layer 120, the passivation layer 130, the color filter array 140 and the planarizing layer 150 has IR cutting capability but an IR cutting layer 180 merely for cutting IR light is inserted. The IR cutting layer 180 may be disposed between the passivation layer 130 and the color filter array 140 as shown in FIG. 2, or alternatively between the dielectric layer 120 and the passivation layer 130, between the color filter array 140 and the planarizing layer 150, or on the planarizing layer 150.

The IR cutting layer 180 may be formed by adding a colorless IR-cutting material in the base material thereof, or is directly formed from a colorless IR-cutting material as a base material.

### Third Embodiment

FIG. 3 illustrates a cross-sectional-view of a dielectric layer and a passivation layer thereon in the structure of a semiconductor image sensor according to the third embodiment of this invention.

In this embodiment, the dielectric layer 120 includes one inter-layer dielectric film 120a and two inter-metal dielectric films 120b and 120c, wherein the inter-layer/inter-metal dielectric films 120a, 120b and 120c are respectively formed with metal lines 127a, 127b and 127c thereon and with contact plugs 128a, 128b and 128c therein, and the passivation layer 130 covers the upmost metal line 127c and the upmost inter-metal dielectric film 120c. When the semiconductor image sensor is a CMOS image sensor, the inter-layer dielectric film 120a covers the gates 124 of the CMOS transistors, while the interconnect structure 126 including the metal lines 127a, 127b and 127c and the contact plugs 128a, 128b and 128c is electrically connected with the gates 124 via some of the contact plugs 128a.

The material of each of the inter-layer/inter-metal dielectric films 120a, 120b and 120c and the passivation layer 130 is a IR-cutting dielectric material transparent to visible lights like Ta₂O₅, TiO₂, SiO, ZrO₂, MoO₂, ZnO₂, InO₂, CrO₂, Al₂O₃, HfO₂ or ZnS, etc., each of which may be deposited with sputtering or PECVD and can reflect and absorb IR light. The thicknesses of the dielectric films 120a, 120b and 120c and the passivation layer 130 can be adjusted to cause destructive interference of IR light as above to further decrease the IR intensity to the photoactive regions 110.

As mentioned above, this invention directly forms over the photoactive region of the semiconductor image sensor an IR cutting layer, which may be a layer merely for cutting IR light or a layer modified from one or more functional layers. Hence, the lens of an image recording apparatus based on a semiconductor image sensor of this invention does not need an IR filter, so that the design/use of the image recording apparatus is simpler and the cost for an IR filter is saved.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A semiconductor image sensor, comprising:
a substrate having at least a photoactive region therein; and
an IR cutting layer disposed over the photoactive region.

2. The semiconductor image sensor of claim 1, wherein the IR cutting layer includes an IR absorption/reflection layer.

3. The semiconductor image sensor of claim 1, wherein the IR cutting layer includes a base material and an IR cutting material added in the base material.

4. The semiconductor image sensor of claim 1, wherein the IR cutting layer includes a base material that is an IR cutting material.

5. The semiconductor image sensor of claim 1, wherein the IR cutting layer is disposed merely for cutting IR light.

6. The semiconductor image sensor of claim 1, wherein the IR cutting layer has at least one function other than IR cutting.

7. The semiconductor image sensor of claim 6, wherein the IR cutting layer also serves as a color filter.

8. The semiconductor image sensor of claim 7, wherein the IR cutting layer comprises a photoresist material containing an IR absorption/reflection dye.

9. The semiconductor image sensor of claim 8, wherein the IR absorption dye is selected from the group consisting of at least cyanine dyes, squarilium dyes, naphthoquinone dyes, quinone imine dyes, quinone diimine dyes, phthalocyanine, tetradehydrocholine and ethylene-1,2-dithiol metal complexes.

10. The semiconductor image sensor of claim 6, wherein the IR cutting layer also serves as a dielectric layer.

11. The semiconductor image sensor of claim 10, wherein the dielectric layer include at least one of a plurality of inter-layer/inter-metal dielectric films.

12. The semiconductor image sensor of claim 10, wherein the dielectric layer comprises a material selected from the group consisting of at least Ta₂O₅, TiO₂, SiO, ZrO₂, MoO₂, ZnO₂, InO₂, CrO₂, Al₂O₃, HfO₂ and ZnS.

13. The semiconductor image sensor of claim 6, wherein the IR cutting layer also serves as a passivation layer or a planarizing layer.

14. The semiconductor image sensor of claim 6, wherein the IR cutting layer includes a plurality of functional layers having different functions other than IR cutting.

15. The semiconductor image sensor of claim 14, wherein the functional layers include at least two of a dielectric layer, a passivation layer, a color filter and a planarizing layer that are stacked from bottom to top.

16. The semiconductor image sensor of claim 15, wherein the functional layers include the dielectric layer and the passivation layer;
the dielectric layer include a plurality of inter-layer/inter-metal dielectric films; and
the inter-layer/inter-metal dielectric films and the passivation comprise at least one material selected from the group consisting of at least Ta₂O₅, TiO₂, SiO, ZrO₂, MoO₂, ZnO₂, InO₂, CrO₂, Al₂O₃, HfO₂ and ZnS.

17. The semiconductor image sensor of claim 1, further comprising a microlens disposed over the IR cutting layer over the photoactive region.

18. The semiconductor image sensor of claim 1, which is a CMOS image sensor (CIS) or a charge coupled device (CCD) image sensor.

19. A semiconductor image sensor, comprising:
a substrate having therein at least a plurality of photoactive regions arranged in an array;
a dielectric layer on the substrate, having a circuit therein;
a passivation layer on the dielectric layer;
an array of color filters on the passivation layer, each color filter being disposed over one photoactive region;
a planarizing layer covering the color filter array; and
an IR cutting layer over the photoactive region.

20. The semiconductor image sensor of claim 19, wherein the IR cutting layer includes at least one of the dielectric layer, the passivation layer, the array of color filters and the planarizing layer.

21. The semiconductor image sensor of claim 19, wherein the IR cutting layer is disposed between the dielectric layer and the passivation layer, between the passivation layer and the array of color filters or between the array of color filters and the planarizing layer, or is disposed on the planarizing layer.

22. The semiconductor image sensor of claim 19, wherein the IR cutting layer comprises an IR absorption/reflection layer.

23. The semiconductor image sensor of claim 22, wherein the IR cutting layer comprises the array of color filters.

24. The semiconductor image sensor of claim 23, wherein the array of color filters comprises a photoresist material containing an IR absorption/reflection dye.

25. The semiconductor image sensor of claim 24, wherein the IR absorption dye is selected from the group consisting of at least cyanine dyes, squarilium dyes, naphthoquinone dyes, quinone imine dyes, quinone diimine dyes, phthalocyanine, tetradehydrocholine and ethylene-1,2-dithiol metal complexes.

26. The semiconductor image sensor of claim 19, wherein the dielectric layer includes a plurality of inter-layer/inter-metal dielectric films; and
the IR cutting layer comprises at least one of the inter-layer/inter-metal dielectric films.

27. The semiconductor image sensor of claim 26, wherein the at least one inter-layer/inter-metal dielectric films forming the IR cutting layer comprises a material selected from the group consisting of at least Ta₂O₅, TiO₂, SiO, ZrO₂, MoO₂, ZnO₂, InO₂, CrO₂, Al₂O₃, HfO₂ and ZnS.

28. The semiconductor image sensor of claim 26, wherein the IR cutting layer further comprises the passivation layer.

29. The semiconductor image sensor of claim 28, wherein the passivation layer and the at least one inter-layer/inter-metal dielectric films forming the IR cutting layer comprise at least one material selected from the group consisting of at least Ta₂O₅, TiO₂, SiO, ZrO₂, MoO₂, ZnO₂, InO₂, CrO₂, Al₂O₃, HfO₂ and ZnS.

30. The semiconductor image sensor of claim 19, further comprising:
an array of microlenses on the planarizing layer, each microlens being disposed over one color filter; and
an encapsulant layer covering the array of microlenses and the planarizing layer.

31. The semiconductor image sensor of claim 30, wherein the encapsulant layer is conformal to a surface formed by the array of microlenses and the planarizing layer.

32. The semiconductor image sensor of claim 19, which is a CMOS image sensor (CIS) or a charge coupled device (CCD) image sensor.

33. A method for fabricating a semiconductor image sensor, comprising:
providing a substrate formed with at least a photoactive region therein; and
forming an IR cutting layer over the photoactive region.

34. The method of claim 33, wherein the IR cutting layer comprises an IR absorption/reflection layer.

35. The method of claim 33, wherein the step of forming the IR cutting layer comprises:
forming a layer of a base material of the IR cutting layer over the substrate; and
adding an IR cutting material in the formation of the layer of the base material.

36. The method of claim 33, wherein a base material of the IR cutting layer is an IR cutting material.

37. The method of claim 33, wherein the IR cutting layer is formed merely for cutting IR light.

38. The method of claim 33, wherein the IR cutting layer has at least one function other than IR cutting.

39. The method of claim 38, wherein the IR cutting layer serves as a color filter.

40. The method of claim 39, wherein the IR cutting layer comprises a photoresist material containing an IR absorption/reflection dye.

41. The method of claim 33, wherein the IR cutting layer includes at least two functional layers each having a least one function other than IR cutting.

42. The method of claim 41, wherein the functional layers are formed contiguous or non-contiguous.

43. The method of claim 42, wherein the IR cutting layer comprises a dielectric layer and a passivation layer thereon that are formed contiguous.

44. The method of claim 43, wherein the dielectric layer comprises a plurality of inter-layer/inter-metal dielectric films, and the dielectric films and the passivation layer comprise at least one material selected from the group consisting of at least Ta₂O₅, TiO₂, SiO, ZrO₂, MoO₂, ZnO₂, InO₂, CrO₂, Al₂O₃, HfO₂ and ZnS.

45. The method of claim 33, wherein the semiconductor image sensor is a CMOS image sensor (CIS) or a charge coupled device (CCD) image sensor.
